(19) United States
(12) Patent Application Publication
(10) Pub. No.: US 2022/0367561 A1
(43) Pub. Date: Nov. 17, 2022

(54) HIGH EFFICIENCY InGaN LIGHT EMITTING DIODES

(71) Applicant: THE REGENTS OF THE UNIVERSITY OF MICHIGAN, Office of Technology Transfer, Ann Arbor, MI (US)

(72) Inventors: Xianhe LIU, Ann Arbor, MI (US); Yi SUN, Ann Arbor, MI (US); Yakshita MALHOTRA, Ann Arobr, MI (US); Ayush PANDEY, Ann Arbor, MI (US); Ping WANG, Ann Arbor, MI (US); Yuanpeng WU, Ann Arbor, MI (US); Kai SUN, Ann Arbor, MI (US); Zetian MI, Ann Arbor, MI (US)

(21) Appl. No.: 17/745,753

(22) Filed: May 16, 2022

Related U.S. Application Data
(60) Provisional application No. 63/188,971, filed on May 14, 2021.

(51) Int. Cl. H01L 27/15

(52) U.S. Cl. CPC H01L 27/156

(57) ABSTRACT

In various embodiments, the present disclosure includes a nitrogen-polar (N-polar) nanowire that includes an indium gallium nitride (InGaN) quantum well formed by selective area growth. It is noted that the N-polar nanowire is operable for emitting light.

### CROSS-REFERENCE TO RELATED APPLICATION

This application claims the benefit of U.S. Provisional Patent Application No. 63/188,971 filed on May 14, 2021 entitled “High Efficiency InGaN Nanocrystal Tunnel Junction Micro LEDs,” by Xianhe LIU et al., Attorney Docket No. TRTM-0014.00.00US, which is hereby incorporated by reference.

This application is related to PCT Application No. PCT/US21/18559 filed on Feb. 18, 2021 entitled “Micrometer Scale Light-Emitting Diodes,” by The Regents of the University of Michigan, Attorney Docket No. TRTM-0010-01S00WO, which claims priority to U.S. Provisional Patent Application No. 62/978,168 filed on Feb. 18, 2020, which are hereby incorporated by reference.

### BACKGROUND

The microelectronic industry has benefited tremendously from the miniaturization of transistors, e.g., MOSFETs, down to dimensions below 10-100 nm scale. Shrinking the sizes of optoelectronic devices, e.g., light emitting diodes (LEDs) and laser diodes to micro and nanoscale, however, severely deteriorate the device performance. For example, while external quantum efficiency (EQE) in the range of 50-80% can be commonly measured under current densities of 1-26 A/cm² for large area indium gallium nitride (InGaN) blue quantum well LEDs with lateral dimensions on the order of tens to hundreds of micrometers, the efficiency is substantially reduced for nano and microscale devices. Schematically shown in FIG. 1 are some previously reported efficiency values for InGaN LEDs with various sizes and emission colors. The difficulty of realizing high efficiency micro-LEDs has been considered one of the major roadblocks for next generation mobile display, sensing, imaging, and biomedical applications. Moreover, there are virtually no reports on meaningful efficiency values for LEDs with sizes below 1 micrometer (μm). Fundamental challenges include the surface damage induced by etching in the fabrication process and the resulting severe nonradiative surface recombination and poor charge carrier transport and injection in the device active region.

Alternatively, LEDs can be fabricated utilizing nanostructures synthesized by the bottom-up approach. Due to the efficient surface strain relaxation, such nanostructures are largely free of dislocations and exhibit epitaxially smooth surface. In this context, significant attention has been paid to InGaN nanowire-based devices in the past decade. Full-color emission has been demonstrated for InGaN nanowires grown in a single epitaxy step by controlling their size and spacing, thereby enabling transfer-free monolithic full color LED arrays. Quantum dot-in-nanowires, core-shell heterostructures and tunnel junction have also been developed to reduce nonradiative surface recombination and to significantly enhance charge carrier injection efficiency. To date, however, these studies have been largely focused on Ga-polar structures, which are often characterized by the presence of pyramid-like surface morphology when grown along the c-axis. Moreover, there have been few reports on the performance and efficiency for such devices at the micro- and nanoscale.

Recent advances have shown that N-polar structures can offer significant performance advantages compared to their Ga-polar counterparts. N-polar III-nitrides can be grown at relatively higher temperatures, thereby significantly reducing the formation of point defects, which is critical for achieving high efficiency emission in the deep visible. N-polar InGaN nanowires grown along the c-axis exhibit flat top surface, which can greatly simplify the device fabrication process and improve the yield. Studies have also suggested that N-polar InGaN LEDs can exhibit reduced electron overflow and is therefore well suited for high power operation. Moreover, N-polar III-nitride nanostructures can be grown under N-rich epitaxy conditions, which can enable efficient p-type conduction by suppressing N vacancy related defect formation. Previous studies of N-polar LEDs, however, were largely focused on spontaneously grown nanowires with random distribution of size, spacing and morphology.

### SUMMARY

Various embodiments in accordance with the present disclosure can address the disadvantages described above.

In various embodiments, the present disclosure includes a nitrogen-polar (N-polar) nanowire that includes an indium gallium nitride (InGaN) quantum well formed by selective area growth. It is noted that the N-polar nanowire is operable for emitting light.

In various embodiments, the N-polar nanowire is a light emitting diode (LED).

In various embodiments, the N-polar nanowire LED has an external quantum efficiency (EQE) greater than 10%.

In various embodiments, the N-polar nanowire LED has an external quantum efficiency (EQE) greater than 10% and includes a lateral dimension less than 1 micrometer.

In various embodiments, the N-polar nanowire LED has a lateral dimension less than 1 micrometer.

In various embodiments, the N-polar nanowire includes a lateral dimension less than 1 micrometer.

In various embodiments, the N-polar nanowire LED has an external quantum efficiency (EQE) greater than 10% and the light comprises green light.

In various embodiments, the N-polar nanowire includes a plurality of InGaN quantum disks and a plurality of aluminum gallium nitride (AlGaN) barrier layers.

In various embodiments, the N-polar nanowire further includes a p-doped AlGaN layer.

In various embodiments, the N-polar nanowire further includes an InGaN layer.

In various embodiments, the present disclosure includes a light emitting diode (LED) including an N-polar nanowire formed by selective area growth, where the LED comprises a lateral dimension less than 1 micrometer.

In various embodiments, the N-polar nanowire further comprises an InGaN layer.

In various embodiments, the LED is operable for emitting green light.

In various embodiments, the LED has an external quantum efficiency (EQE) greater than 10%.

In various embodiments, the N-polar nanowire further includes a plurality of quantum disks.

In various embodiments, the N-polar nanowire further includes an AlGaN quantum barrier layer.

In various embodiments, the selective area growth includes selective area epitaxy.

In various embodiments, the present disclosure includes a light emitting diode (LED) including a plurality of nanowires, where each of the plurality of nanowires includes a tunnel junction. In addition, the LED includes a conformal passivation layer formed by atomic layer deposition (ALD) between the plurality of nanowires. Note that the LED is operable for emitting light and an external quantum efficiency (EQE) greater than 5%. Furthermore, the LED is in the range of 1-10 micrometers in lateral dimension.

In various embodiments, the conformal passivation layer comprises Al₂O₃.

In various embodiments, the conformal passivation layer comprises an oxide.

While various embodiments in accordance with the present disclosure have been specifically described within this Summary, it is noted that the claimed subject matter are not limited in any way by these various embodiments.

### BRIEF DESCRIPTION OF THE DRAWINGS

The accompanying drawings, which are incorporated in and form a part of this specification and in which like numerals depict like elements, illustrate embodiments of the present disclosure and, together with the detailed description, serve to explain the principles of the disclosure. The drawings are not necessarily to scale.

FIG. 1 is a graph of variations of peak external quantum efficiency (EQE) of InGaN/GaN LEDs vs. lateral dimension for some reported devices.

FIG. 2A is a schematic of an N-polar GaN template grown on a substrate in accordance with various embodiments of the present disclosure.

FIG. 2B is a schematic of a patterned N-polar n-GaN template on the substrate using a mask in accordance with various embodiments of the present disclosure.

FIG. 2C is a schematic of InGaN/GaN nanowires formed by selective area epitaxy along with a schematic of the LED heterostructure in accordance with various embodiments of the present disclosure.

FIG. 2D is a scanning electron microscopy (SEM) image of nanowires in accordance with various embodiments of the present disclosure.

FIG. 2E is a graph of a photoluminescence spectra measured from InGaN nanowires with various indium compositions in the quantum disk active region in accordance with various embodiments of the present disclosure.

FIG. 3A is a scanning transmission electron microscopy high angle annular dark field (STEM-HAADF) image of a single InGaN/AlGaN nanowire with six stacks of InGaN quantum disks exhibiting green emission in accordance with various embodiments of the present disclosure.

FIG. 3B is a high magnification of the region around the quantum disks in accordance with various embodiments of the present disclosure.

FIG. 3C is an elemental mapping of In and Al in the region denoted by the box in FIG. 3B in accordance with various embodiments of the present disclosure.

FIG. 3D is the profile of Al distribution along the dashed line in FIG. 3B in accordance with various embodiments of the present disclosure.

FIG. 3E is a high magnification STEM (scanning transmission electron microscopy) annular bright-field image showing the atomic stack order where larger circles represent Ga and smaller circles represent N in accordance with various embodiments of the present disclosure.

FIG. 4A is a graph of current-voltage (I-V) characteristics of a submicron InGaN nanowire LED and the inset is an SEM image of the current injection window of the device in accordance with various embodiments of the present disclosure.

FIG. 4B is a graph of representative electroluminescence spectra of a N-polar submicron-LED and the inset is an optical microscopy image of the device in accordance with various embodiments of the present disclosure.

FIG. 5A is a graph of variations of output power with current density in accordance with various embodiments of the present disclosure.

FIG. 5B is a graph of variations of external quantum efficiency (EQE) with current density in accordance with various embodiments of the present disclosure.

FIG. 6 is a graph in accordance with various embodiments of the present disclosure.

FIG. 7A is a schematic of the InGaN nanowire micro-LED and the device heterostructure in accordance with various embodiments of the present disclosure.

FIG. 7B is a scanning electron microscopy (SEM) image of the as grown sample in accordance with various embodiments of the present disclosure.

FIG. 7C is a large area SEM image of the as grown sample in accordance with various embodiments of the present disclosure.

FIG. 8A is a STEM-HAADF image of a single core-shell nanowire with InGaN/AlGaN multiple quantum disks in accordance with various embodiments of the present disclosure.

FIG. 8B shows the Distribution of In (top), Ga (center), and Al (bottom) around the active region measured by energy-dispersive X-ray spectroscopy in accordance with various embodiments of the present disclosure.

FIG. 8C is a High magnification HAADF image of the region corresponding to the dashed box in FIG. 8A in accordance with various embodiments of the present disclosure.

FIG. 8D is a graph of the profile of Al distribution along the solid line in FIG. 8C in accordance with various embodiments of the present disclosure.

FIG. 9A is a graph of current-voltage characteristics of an InGaN nanowire micro-LED with a size of approximately 3 μm×3 μm together with a photo of the device taken under room light in accordance with various embodiments of the present disclosure.

FIG. 9B is a graph of electroluminescence spectra measured under different injection current densities at room temperature in accordance with various embodiments of the present disclosure.

FIG. 10A is a graph in accordance with various embodiments of the present disclosure.

FIG. 10B is a graph of a summary of normalized peak EQE of devices with different dimensions in accordance with various embodiments of the present disclosure.

FIG. 10C is a graph of normalized EQE of some representative devices with different lateral dimensions in accordance with various embodiments of the present disclosure.

FIG. 11 is a graph in accordance with various embodiments of the present disclosure.

### DETAILED DESCRIPTION

Reference will now be made in detail to various embodiments in accordance with the present disclosure, examples of which are illustrated in the accompanying drawings. While described in conjunction with various embodiments, it will be understood that these various embodiments are not intended to limit the present disclosure. On the contrary, the present disclosure is intended to cover alternatives, modifications and equivalents, which may be included within the scope of the present disclosure. Furthermore, in the following detailed description of various embodiments in accordance with the present disclosure, numerous specific details are set forth in order to provide a thorough understanding of the present disclosure. However, it will be evident to one of ordinary skill in the art that the present disclosure may be practiced without these specific details or with equivalents thereof. In other instances, well known methods, procedures, components, and circuits have not been described in detail as not to unnecessarily obscure aspects and features of the present disclosure.

The figures of the present disclosure are not necessarily drawn to scale, and only portions of the devices and structures may be depicted, as well as the various layers that form those structures, are shown. For simplicity of discussion and illustration, only one or two devices or structures may be described, although in actuality more than one or two devices or structures may be present or formed. Also, while certain elements, components, and layers are discussed, embodiments in accordance with the present disclosure are not limited to those elements, components, and layers. For example, there may be other elements, components, layers, and the like in addition to those discussed.

Some portions of the detailed descriptions that follow are presented in terms of procedures and other representations of operations for fabricating devices like those disclosed herein. These descriptions and representations are the means used by those skilled in the art of device fabrication to most effectively convey the substance of their work to others skilled in the art. In the present application, a procedure, operation, or the like, is conceived to be a self-consistent sequence of steps or instructions leading to a desired result. Operations described as separate blocks may be combined and performed in the same process step (that is, in the same time interval, after the preceding process step and before the next process step). Also, the operations may be performed in a different order than the order in which they are described below. Furthermore, fabrication processes and steps may be performed along with the processes and steps discussed herein; that is, there may be a number of process steps before, in between, and/or after the steps shown and described herein. Importantly, embodiments according to the present disclosure can be implemented in conjunction with these other (perhaps conventional) processes and steps without significantly perturbing them. Generally speaking, embodiments according to the present disclosure can replace portions of a conventional process without significantly affecting peripheral processes and steps.

N-Polar InGaN Nanowires: High Efficiency Nano and Micro LEDs

The efficiency of conventional quantum well light emitting diodes (LEDs) decreases drastically with reducing areal size. In accordance with various embodiments of the present disclosure, such a critical size scaling issue of LEDs can be addressed by utilizing N-polar InGaN nanowires. Note that in various embodiments, the epitaxy and performance characteristics were studied of N-polar InGaN nanowire LEDs grown on sapphire substrate by plasma-assisted molecular beam epitaxy and a maximum external quantum efficiency (EQE) approximately 11% was measured for LEDs with lateral dimensions as small as 750 nm directly on wafer without any packaging. Various embodiments of the present disclosure provide a viable approach for achieving high efficiency nano and micro-LEDs that were not previously possible.

In various embodiments, the present disclosure reports on the demonstration of high efficiency N-polar InGaN nanowire sub-micron LEDs operating in the green wavelength. In various embodiments, N-polar InGaN nanowires with the incorporation of multiple InGaN quantum disks were grown on N-polar GaN template on sapphire substrate. A maximum external quantum efficiency approximately 11% was measured for LEDs with dimensions as small as 750 nm directly on wafer without any packaging. In various embodiments, detailed analysis also show that the room temperature internal quantum efficiency (IQE) is in the range of 60% for a green-emitting nanowire LED at an injection current density approximately 1 A/cm². In various embodiments, the present disclosure provides a viable approach to address the size scaling issue associated with conventional quantum well LEDs, thereby enabling high efficiency nano and micro-LEDs that were not previously possible.

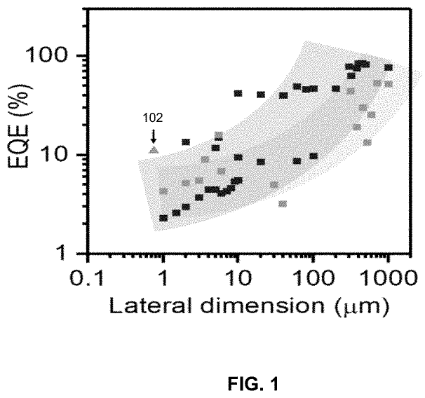

FIG. 1 is a graph showing variations of peak external quantum efficiency (EQE) of InGaN/GaN LEDs vs. lateral dimension for some reported devices in the literature, showing the significantly reduced efficiency with decreasing device size. In addition, it is noted that the dark colored squares within FIG. 1 represent blue LEDs while the light colored represent green LEDs. Furthermore, note that light colored triangle 102 represents a green LED in accordance with an embodiment of the present disclosure that has an EQE greater than 10% and has a lateral dimension less than 1 micrometer.

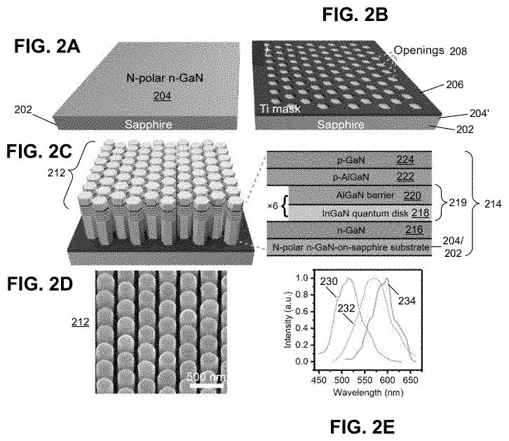

FIGS. 2A-2C are schematics illustrating a process for forming N-polar InGaN nanowires 212 that each include a LED heterostructure 214 in accordance with various embodiments of the present disclosure. Note that the process of FIGS. 2A-2C includes selective area growth.

FIG. 2A is a schematic of an N-polar GaN template 204 grown on a substrate 202 (e.g., wafer) in accordance with various embodiments of the present disclosure. In various embodiments, note that the substrate 202 can be implemented with, but is not limited to, a sapphire wafer, a silicon wafer, or a gallium nitride (GaN) wafer. In addition, within the present embodiment the template 204 is an N-polar n-doped GaN template as shown in FIG. 2A. In various embodiments, the N-polar GaN templates 204 can be grown on sapphire substrate 202 using a Veeco GENxplor plasma-assisted molecular beam epitaxial (PAMBE) system. Moreover, sufficient nitridation of the substrate can be firstly performed in situ at 400° C. Then a GaN buffer layer can be grown at 650° C. In an embodiment, the N-polar GaN epilayer 204 had a thickness approximately 800 nm and was doped n-type with Si.

FIG. 2B is a schematic of a patterned N-polar n-GaN template 204′ on the substrate using a titanium (Ti) mask 206 in accordance with various embodiments of the present disclosure. In various embodiments, to perform selective area epitaxy (SAE) on N-polar GaN templates 204, a patterning process is adopted, schematically shown in FIG. 2B. Note that selective area epitaxy (SAE) can also be referred to as selective area growth. In various embodiments, a 10 nm thick Ti layer was firstly deposited by electron beam evaporation, which was followed by electron beam lithography and dry etching of Ti. The resist was then removed, and the patterns were thoroughly cleaned for growth. The schematic of the patterned substrate with periodic array of openings 208 in the Ti layer 206 (e.g., mask) is illustrated in FIG. 2B. The following process is in accordance with various embodiments of the present disclosure. For example, the growth was performed in a Veeco Gen 930 PAMBE system. Nitridation of the substrate with patterned Ti mask 206 was firstly performed in situ at 400° C. for 10 minutes to avoid the formation of cracks of the Ti mask 206 during growth. Under optimized conditions, epitaxy of GaN was suppressed on the surface of Ti mask 206 due to the high desorption rate of Ga adatoms, thereby allowing for growth only in the openings 208 as illustrated in FIG. 2C.

FIG. 2C is a schematic of N-polar InGaN/GaN nanowires 212 formed by selective area epitaxy along with a schematic of the LED heterostructure 214 in accordance with various embodiments of the present disclosure. It is noted that each of the N-polar InGaN/GaN nanowires 212 can be referred to as a LED. In addition, note that each of the InGaN/GaN nanowires 212 includes the LED heterostructure 214 which includes an n-GaN nanowire template 216, an active region 219 consisting of six stacks of InGaN quantum disks 218 and AlGaN barriers 220, a p-AlGaN layer 222, and a p-GaN layer 224. In various embodiments, the n-GaN nanowire template 216 was grown using a Ga BEP of approximately 4×10⁻⁷ Torr and a nitrogen flow rate of 0.7 sccm at a pyrometer temperature of 670° C. In various embodiments, the InGaN/AlGaN quantum disk active region 219 was grown at a reduced temperature of 500° C. measured by pyrometer. The subsequent growth of p-Ga(Al)N was performed using a Ga BEP of approximately 4×10⁻⁷ Torr and an Al BEP of 8.7×10⁻⁹ Torr, and a nitrogen flow rate of 0.64 sccm at a temperature of 670° C. The p-AlGaN layer 224 is designed to be approximately 20 nm thick. The incorporation of Al in the barriers and the p-AlGaN layer 222 promotes the formation of an Al-rich AlGaN shell, which can significantly reduce nonradiative surface recombination and enable high efficiency emission.

In various embodiments, the fabrication of micro-LEDs 212 started with surface passivation of the nanowires 212. In addition, a 50 nm Al₂O₃ was deposited by atomic layer deposition at 250° C. and then etched back with inductively coupled plasma to reveal the top part of nanowires 212 for p-metal contact deposition. The Al₂O₃ layer on the nanowire sidewalls remained for passivation purpose. An additional SiO₂ layer was deposited by plasma-enhanced chemical vapor deposition. Submicron current injection windows on top of nanowire crystals were made using standard lithography and dry etching of SiO₂ and Al₂O₃. The current injection window for n-metal contact deposition on the template was formed simultaneously. Then a stack of 5 nm Ni/5 nm Au/180 nm indium tin oxide (ITO) was deposited on the nanowires 212 and annealed at 550° C. for 1 min in 5% H₂ and 95% N₂ ambient. A stack of 5 nm Ti/30 nm Au was deposited on the N-polar n-GaN template 204′ to serve as the n-contact. To enhance light extraction, top reflecting layers consisting of 50 nm Ag, 150 nm Al and 50 nm Au were deposited on the device top surface.

### Material Characterizations

FIG. 2D is a scanning electron microscopy (SEM) image of nanowires (e.g., 212) in accordance with various embodiments of the present disclosure. FIG. 2E is a graph of a photoluminescence (PL) spectra measured from InGaN nanowires with various indium compositions in the quantum disk active region (e.g., 219) in accordance with various embodiments of the present disclosure. In various embodiments, the N-polar nanowires 212 formed in this process exhibit highly uniform dimension and morphology, shown in FIGS. 2D and 2E, which is in direct contrast to the uncontrolled properties for previously reported N-polar nanowires by spontaneous growth process. The nanowires formed by SAE maintains the same polarity as the GaN template 216. Unlike Ga-polar nanowires, N-polar nanowires have a flat morphology on the top, which is the polar c-plane. Therefore, the InGaN quantum disks 218 are expected to reside on the polar plane, which is similar to that of conventional InGaN quantum well LED devices, except without the formation of extensive defects and dislocations. The emission wavelengths can be controllably tuned by varying the compositions and/or sizes of the disks, as shown by representative spectra in FIG. 2E exhibiting different peak positions and colors. The PL measurements were performed at room temperature using a 405 nm laser with an incident power of approximately 5 mW. The cyan color emission 230 and green color emission 232 in FIG. 2E were achieved from two nanowire arrays on the same sample grown under the aforementioned condition by exploiting the geometry-dependent In incorporation. The orange color emission 234 in FIG. 2E was achieved from another sample using a higher (1.4 sccm) nitrogen flow rate to enhance In incorporation with other conditions remaining identical.

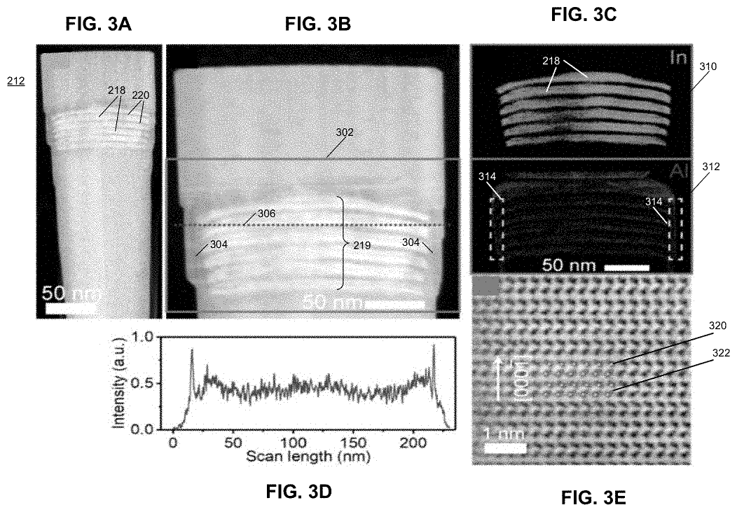

In various embodiments, the structural properties were characterized for a calibration nanowire sample exhibiting green emission using scanning transmission electron microscopy (STEM). FIG. 3A is a scanning transmission electron microscopy high angle annular dark field (STEM-HAADF) image of a single InGaN/AlGaN nanowire (e.g., 212) with six stacks of InGaN quantum disks (e.g., 218) exhibiting green emission in accordance with various embodiments of the present disclosure. FIG. 3B is a high magnification of the region around the quantum disks 218 in accordance with various embodiments of the present disclosure. Shown in FIG. 3A, the nanowire 212 clearly exhibits a flat morphology due to the N-polarity. The relatively light gray layers are the InGaN quantum disks 218, and the relatively dark gray layers correspond to the AlGaN barriers 220. A high magnification image around the active region 219 is shown in FIG. 3B.

To reveal the structure of the active region 219, energy-dispersive X-ray spectroscopy was performed for the distribution of In and Al in the region in the box 302 in FIG. 3B. FIG. 3C is an elemental mapping of In and Al in the region denoted by the box 302 in FIG. 3B in accordance with various embodiments of the present disclosure. The top panel 310 in FIG. 3C confirms the formation of vertically stacked InGaN quantum disks 218. Unlike conventional InGaN quantum wells which commonly have disorders, such InGaN quantum disks 218 in nanowires 212 exhibited extensive atomic ordering. Comparing with the distribution of Al in the bottom panel 312 of FIG. 3C, there is clearly spatial overlap between the distributions of In and Al. In various embodiments, the thickness of each In-containing layer 218 is designed to be approximately 6-7 nm, but the actual thickness may vary, depending on the lateral indium migration as well as interfacial atom diffusion. It is also seen that the In distribution of the bottom three InGaN layers 218 exhibits a relatively dark region, suggesting a low In content in these regions, which may further contribute to the linewidth broadening of the emission spectra. Furthermore, the distribution of Al in the bottom panel 312 of FIG. 3C clearly exhibits Al-rich shell structure indicated by the dashed boxes 314. This Al-rich AlGaN shell is also visible in FIG. 3B which has vertical dark gray lines 304 surrounding the InGaN quantum disks 218 near the sidewall of the nanowire 212. Such Al-rich AlGaN shell structure can effectively confine charge carriers in the InGaN quantum disks 218 and substantially minimize surface nonradiative recombination on the sidewalls, leading to enhanced emission efficiency. A line scan for the Al distribution was performed along the dashed line 306 in FIG. 3B. FIG. 3D is the profile of Al distribution along the dashed line 306 in FIG. 3B in accordance with various embodiments of the present disclosure. The signal intensity in FIG. 3D exhibits two pronounced peaks near the surface of the nanowire 212, which further confirms the presence of Al-rich AlGaN shell. The spontaneous formation of such Al-rich AlGaN shell is driven by the different surface migration lengths of Al adatoms. As Al adatoms have shorter migration lengths than Ga and In adatoms, those impinging on the sidewalls cannot reach the top flat surface but rather bond with N locally. However, most Ga and In adatoms can efficiently migrate to the top flat surface and contribute to epitaxy in the vertical direction, leading to Ga/In deficiency on the sidewalls. In various embodiments, the resultant Al-rich shell is critical for suppressing surface nonradiative recombination and enhance light output. It is important to note that Ga-polar nanowires with typical pyramid top morphology also exhibit Al-rich shell structure which is however formed differently along the semipolar planes. Individual Ga and N atoms, denoted by larger circles 320 and smaller circles 322, respectively, are clearly resolved in a high resolution image, shown in FIG. 3E, which further confirms the N-polarity of InGaN nanostructures. FIG. 3E is a high magnification STEM (scanning transmission electron microscopy) annular bright-field image showing the atomic stack order where larger circles 320 represent Ga and smaller circles 322 represent N in accordance with various embodiments of the present disclosure.

### Current-Voltage Characteristics and Emission Efficiency

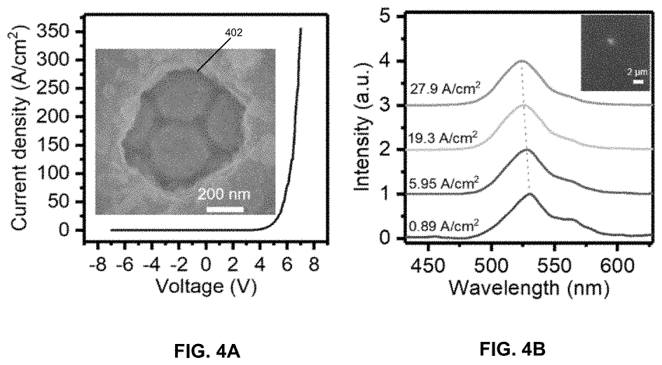

FIG. 4A is a graph of current-voltage (I-V) characteristics of a submicron InGaN nanowire LED 212 and the inset is an SEM image of the current injection window 402 of the device in accordance with various embodiments of the present disclosure. A turn-on voltage of approximately 4.5 V is measured with a negligibly small reverse bias leakage, suggesting the well-formed junction. The relatively high turn-on voltage is partly related to the etching of the top p-GaN layer 224 during the fabrication process and the resulting large contact resistance. The turn-on voltage can be reduced by optimizing the fabrication process. A relatively high current density of approximately 350 A/cm² can be readily reached at 7 V, indicating efficient charge carrier transport in the N-polar nanowires 212. The calculated current density considers the real size of the current injection window 402 as shown in the inset of FIG. 4A and the fill factor of the nanowire array 212. It is seen that only approximately four nanowires 212 were located within this current injection window 402. Given that no degradation of I-V characteristics was seen for such small devices at a relatively high bias, the nanowires 212 prove to be suited for relatively high power and high brightness operation. The leakage current under reverse bias is very low, which is close to the measurement limit of the instrument. FIG. 4B is a graph of representative electroluminescence spectra of a N-polar submicron-LED 212 and the inset is an optical microscopy image of the device 212 in accordance with various embodiments of the present disclosure. Electroluminescence spectra with a main peak at approximately 530 nm were measured at room temperature as shown in FIG. 4B. A weak shoulder at 563 nm, which is likely due to the size dispersion of the disks, is also measured at a low current density. As the current density increases, the main peak becomes dominant and remains stable with a small peak wavelength shift from 530 nm to 524 nm and a slight broadening of full-width at half-maximum from 36.6 nm to 37.8 nm. Both the peak shift and spectral broadening with injection current are substantially improved compared to conventional Ga-polar quantum well LEDs. The inset of FIG. 4B shows the device 212 under room light illumination. In various embodiments, further optimization in the InGaN growth condition is expected to improve the homogeneity among InGaN disks and thereby eliminate any parasitic emission.

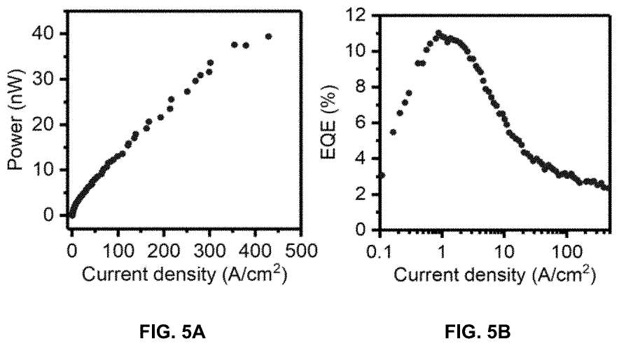

FIG. 5A is a graph of variations of output power with current density in accordance with various embodiments of the present disclosure. In addition, FIG. 5B is a graph of variations of external quantum efficiency (EQE) with current density in accordance with various embodiments of the present disclosure. In various embodiments, the output power and EQE were measured by directly placing the device (e.g., 212) on a Si detector. A Keithley 2400 was used as the source meter for current injection. A Si detector (Newport 818-ST2-UV/DB) together with a power meter (Newport 1919-R) were used for the output power measurement. During the measurements in an embodiment, the device (e.g., 212) was placed on top of the Si detector, and light emitted from the backside of the sapphire substrate (e.g., 202) was collected and recorded. Shown in FIG. 5A, the output power showed a nearly linear increase with injection current. Variations of the EQE with current is shown in FIG. 5B. The measured EQE showed a rapid increase with injection current and reached a peak value of approximately 11% at a relatively small current density of 0.83 A/cm², indicating a small contribution from Shockley-Read-Hall recombination or surface nonradiative recombination. This variation of EQE is similar to conventional high efficiency quantum well LEDs. The reduced quantum confinement Stark effect (QCSE) associated with N-polarity may not be the dominant factor for the high EQE because our Ga-polar nanowire device exhibits a lower EQE of approximately 5.5% despite that the active region resides on the semi-polar planes with less QCSE. The EQE, however, exhibited a drop by half when the current density reached 12.6 A/cm². The severe efficiency droop can be partly explained by the presence of significant electron overflow, as described below.

### Analysis on the Light Emission Efficiency

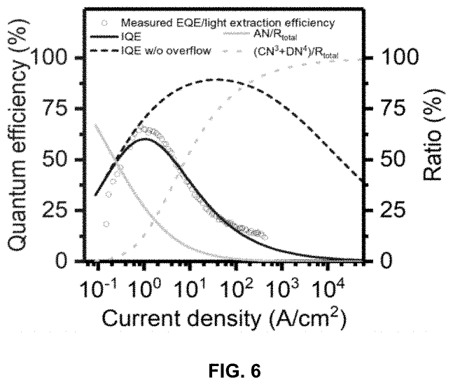

FIG. 6 is a graph in accordance with various embodiments of the present disclosure. For example, the ABC model with an additional term DN⁴ was used to analyze the LED (e.g., 212) performance. Considering the small dimension of the device (e.g., 212) and the resultant heating effect under high bias, only data below 30 A/cm² were used for analysis. By assuming 1×10⁻¹¹ cm³ s⁻¹ for B and an equivalent total disk thickness of 40 nm, other coefficients can be estimated as follows: A=1.37×10⁶ s⁻¹, C=6.97×10⁻³² cm⁶ s⁻¹, and D=2.27×10⁻⁴⁷ cm⁹ s⁻¹. The variation of the contribution from each term is shown in FIG. 6. A relatively high peak IQE of approximately 60% is derived, which is comparable to some of the relatively high IQE values reported in the literature for InGaN epilayers and nanowires. It is seen that the contributions from CN³ and DN⁴ become quickly dominant as the current reaches approximately 6-7 A/cm², confirming the presence of significant electron overflow which was indicated by the fast drop of measured EQE. Therefore, in various embodiments, the device efficiency can be further enhanced and the peak EQE can occur at higher current density upon the improvement of device structure and reduction of electron overflow by optimizing the doping level and the electron blocking layer or superlattice structure. As shown in the inset of FIG. 4A, such nanoscale LEDs consist of only few nanowires 212, with approximately half of them being partially contacted. The highly asymmetric injection of electrons and holes is expected to lead more severe electron overflow effect than a conventional device. In various embodiments, such a critical issue can be addressed through proper patterning and design, which will lead to further enhanced EQE. In various embodiments, it is worthwhile mentioning that the heating effect in the local region on the submicron scale also contribute to the efficiency droop, which can be minimized by reducing the device resistance with further optimization of fabrication process and device structure.

In various embodiments, the performance limit for such N-polar InGaN nanowire micro-LEDs (e.g., 212) have been analyzed. For a well-designed device (e.g., 212), it is expected that the efficiency droop will be predominantly determined by Auger recombination. For example, in an embodiment, for an Auger coefficient approximately 2.6×10⁻³¹ cm⁶ s⁻¹ as commonly reported for InGaN quantum wells, the maximum IQE is estimated to be approximately 89% at room temperature, shown as the darker dashed curve in FIG. 6. In various embodiments, the maximum achievable EQE is estimated to be >60%, assuming a modestly high light extraction efficiency approximately 70% with proper device packaging. In various embodiments, it is also noticed that the peak IQE occurs at an injection current density approximately 38 A/cm², which is significantly higher than that of conventional InGaN quantum well LEDs. This is due to the use of relatively thicker InGaN quantum wells/disks 218 in the active region 219. The thicker disks 218 can reduce carrier density (N) for the same injection current, thereby leading to reduced efficiency droop caused by Auger recombination (∝ N³). This is one of the principal advantages of InGaN nanowires 212, as relatively thick quantum wells/disks 218 can be incorporated in InGaN nanowires 212 without generating extensive defects and dislocations. Such thick active region 219 is favorable for high output power operation under high current injection. Together with the minimization of defect density and surface nonradiative recombination by N-polar nanowire structure 212 and Al-rich shell, high efficiency can be expected under both low current injection and high current injection.

With reference to FIG. 6, Left axis: IQE (solid darker curve) derived based on the ABC model analysis. The estimated IQE (circles) based on the measured EQE divided by the light extraction efficiency is also shown for comparison. Right axis: estimated contribution of AN (light grey solid curve) and CN³+DN⁴ (light grey dotted curve) to the total recombination rate. The IQE, or maximum achievable EQE (dashed darker curve) is further estimated for a well-designed InGaN nanowire LED (e.g., 212) assuming negligible electron overflow, showing a peak IQE approximately 89%.

In conclusion, N-polar InGaN nanowires (e.g., 212) can enable high efficiency submicron-scale LEDs (e.g., 212) that were not previously possible. The peak IQE is estimated to be approximately 60% by fitting with ABC model. Based on various embodiments, it is suggested that N-polar nano and micro-LEDs (e.g., 212) can exhibit maximum achievable EQE potentially exceeding 60% in the deep visible upon full optimization of material quality, carrier injection, and light extraction in the future, which is nearly one order of magnitude higher than that by conventional quantum well devices. In various embodiments, the device (e.g., 212) performance can be further improved by optimizing the design and fabrication process and by utilizing the special technique of tunnel junction. With high efficiency and ultrastable operation, N polar nanowires (e.g., 212) have emerged as suitable building blocks for future ultrahigh resolution, ultrahigh efficiency mobile displays, TVs, and virtual reality systems.

Note that the following are examples in accordance with various embodiments of the present disclosure.

Example 1. A nitrogen-polar (N-polar) nanowire including:
an indium gallium nitride (InGaN) quantum well formed by selective area growth;
wherein the N-polar nanowire is operable for emitting light.

Example 2. The N-polar nanowire of Example 1, wherein the N-polar nanowire is a light emitting diode (LED).

Example 3. The N-polar nanowire of Example 2, wherein the N-polar nanowire LED has an external quantum efficiency (EQE) greater than 10%.

Example 4. The N-polar nanowire of Example 3, wherein the N-polar nanowire LED includes a lateral dimension less than 1 micrometer.

Example 5. The N-polar nanowire of Example 2, wherein the N-polar nanowire LED includes a lateral dimension less than 1 micrometer.

Example 6. The N-polar nanowire of Example 1, wherein the N-polar nanowire includes a lateral dimension less than 1 micrometer.

Example 7. The N-polar nanowire of Example 3, wherein the light includes green light.

Example 8. The N-polar nanowire of Example 1, wherein the N-polar nanowire includes a plurality of InGaN quantum disks and a plurality of aluminum gallium nitride (AlGaN) barrier layers.

Example 9. The N-polar nanowire of Example 1, further including a p-doped AlGaN layer.

Example 10. The N-polar nanowire of Example 1, further including an InGaN layer.

Example 11. A light emitting diode (LED) including:
an N-polar nanowire formed by selective area growth; and
wherein the LED includes a lateral dimension less than 1 micrometer.

Example 12. The LED of Example 11, wherein the N-polar nanowire further includes an InGaN layer.

Example 13. The LED of Example 11, wherein the LED is operable for emitting green light.

Example 14. The LED of Example 13, wherein the LED has an external quantum efficiency (EQE) greater than 10%.

Example 15. The LED of Example 11, wherein the N-polar nanowire further includes a plurality of quantum disks.

Example 16. The LED of Example 11, wherein the N-polar nanowire further includes an AlGaN quantum barrier layer.

Example 17. The LED of Example 11, wherein the selective area growth includes selective area epitaxy.

Example 18. An N-polar nanowire including:
an InGaN layer; and
wherein the N-polar nanowire is a light emitting diode (LED).

Example 19. The N-polar nanowire of Example 18, wherein the selective area growth includes selective area epitaxy.

Example 20. The N-polar nanowire of Example 18 or 19, wherein the LED has an external quantum efficiency (EQE) greater than 10%.

Example 21. The N-polar nanowire of Example 18 or 19 or 20, wherein the N-polar nanowire includes a lateral dimension less than 1 micrometer.

Example 22. The N-polar nanowire of Example 18 or 19 or 20 or 21, wherein the InGaN layer is formed by selective area growth.

Example 23. The N-polar nanowire of Example 18 or 19 or 20 or 21 or 22, wherein the LED is operable for emitting green light.

Example 24. The N-polar nanowire of Example 18 or 19 or 20 or 21 or 22 or 23, wherein the N-polar nanowire further includes an AlGaN quantum barrier layer.

High Efficiency InGaN Nanowire Tunnel Junction Micro LEDs

One embodiment pertains to InGaN nanowire green light emitting diodes (LEDs) with lateral dimensions varying from approximately 1 μm to 10 μm. For a device with an areal size approximately 3 μm×3 μm, a maximum external quantum efficiency approximately 5.5% was measured directly on wafer without any packaging. The efficiency peaks at approximately 3.4 A/cm², and exhibits approximately 30% drop at an injection current density approximately 28 A/cm². Based on various embodiments, it is suggested that a maximum external quantum efficiency in the range of 30-90% can be potentially achieved for InGaN nanowire micro-LEDs by optimizing the light extraction efficiency, reducing point defect formation, and controlling electron overflow. Various embodiments of the present disclosure offer insight for the path to achieve ultrahigh efficiency micro-LEDs operating in the visible.

Nano and microscale light emitting diodes (LEDs) are important for a broad range of applications, including mobile displays, consumer electronics, virtual/augmented/mixed reality, sensing, and biomedical imaging, to name just a few. Since the pioneering demonstration of micro-LEDs nearly two decades ago, significant efforts have been devoted to shrinking the areal sizes of conventional InGaN quantum well devices. Studies have found that etching induced surface damage, structural defects, dangling bonds, and impurity incorporation severely limit both the quantum efficiency and charge carrier (hole) transport and injection into the device active region. Consequently, the efficiency of microscale quantum well LEDs without treatment on the etched sidewall is over one order of magnitude lower compared to state-of-the-art large area devices. For example, a low efficiency approximately 3% was recently reported for an InGaN quantum well blue LED with a mesa diameter of 3 μm. In this regard, various surface passivation techniques have been utilized to enhance the device efficiency. With additional treatment on the sidewall by chemical etching and passivation, the EQE was improved to 10-13% for blue micro LEDs with mesa diameters smaller than 5 μm. Moreover, it has remained extremely challenging to achieve high efficiency green and red LEDs utilizing conventional InGaN quantum wells, due to the presence of large densities of defects, disorders, and dislocations and strong quantum-confined Stark effect (QCSE) with increased indium incorporation.

Recently, significant progress has been made in InGaN nanowires, which are free of dislocations due to the efficient surface strain relaxation. Their emission wavelengths can be controllably tuned across the entire visible spectrum by varying the growth conditions or by varying the nanowire size in a single epitaxy step. Studies showed that InGaN nanowires grown by plasma-assisted molecular beam epitaxy (MBE) are characterized by the presence of extensive atomic ordering, instead of disorders, which promise high efficiency emission and reduced Auger recombination. With lateral dimensions on the order of tens to hundreds of nanometers and epitaxially smooth surface, these nanostructures are well positioned to address the fundamental size scaling issue of micro-LEDs. Moreover, the LED active region can be formed on the abundant semipolar, or nonpolar planes of the nanowires, thereby significantly reducing QCSE and device instability. To date, however, there are few reports on the efficiency of micro-LEDs made of InGaN nanostructures. A detailed understanding of the efficiency limit of such micro-LEDs, including Shockley-Reed-Hall recombination and Auger recombination, has remained elusive.

In various embodiments, the present disclosure reports on the demonstration of relatively high efficiency InGaN nanowire micro-LEDs operating in the green wavelength. A n⁺⁺/p⁺⁺ GaN tunnel junction was incorporated to enhance the hole injection into the active region. The device active region consists of multiple stacks of InGaN/AlGaN quantum disks. The resulting core-shell like structure can significantly reduce nonradiative surface recombination. For a device with an areal size approximately 3 μm×3 μm, a maximum external quantum efficiency (EQE) approximately 5.5% was measured directly on wafer without any packaging. The efficiency peaks at approximately 3.4 A/cm², and exhibits approximately 30% drop in efficiency at an injection current density approximately 28 A/cm². It was shown that the EQE is primarily limited by light extraction. With optimized light extraction efficiency (LEE), reduced point defect formation, and controlled electron overflow, a maximum EQE in the range of 30-90% is attainable for InGaN nanowire micro-LEDs.

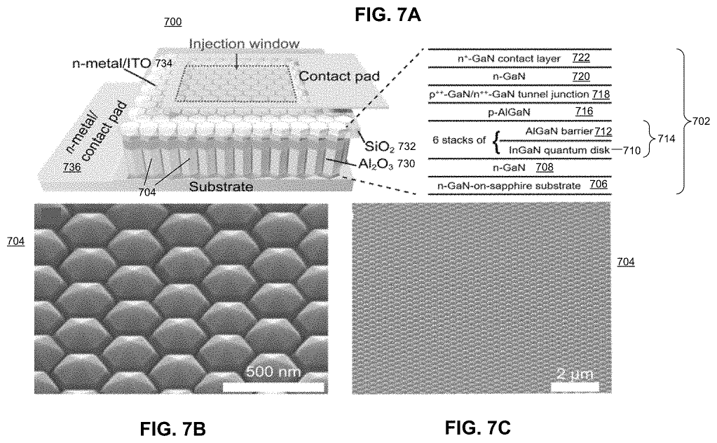

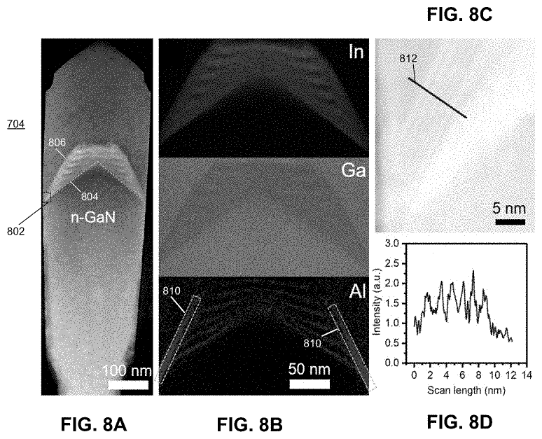

FIG. 7A is a schematic of the InGaN nanowire micro-LED 700 and the device heterostructure 702 in accordance with various embodiments of the present disclosure. In various embodiments, the InGaN nanowire micro-LED 700 includes a plurality or array of InGaN nanowires 704. Note that in various embodiments, each of the InGaN nanowires 704 can be referred to as an LED or an LED structure, but is not limited to such. In various embodiments, the InGaN nanowires 704 were formed by selective area epitaxy (SAE) on a patterned 1 cm×1 cm Si-doped GaN-on-sapphire substrate 706. Note that substrate 706 can be implemented with, but is not limited to, a sapphire wafer, or a silicon wafer. The patterning process was initiated with the deposition of a thin (approximately 10 nm) Ti layer on GaN template to serve as the growth mask. Arrays of openings were subsequently defined by electron beam lithography and dry etching of Ti. The patterned substrate was thoroughly cleaned after removal of the resist. The growth was performed in a Veeco GEN 930 molecular beam epitaxial system equipped with a radio frequency plasma-assisted nitrogen source. The growth conditions were carefully optimized to enable the epitaxy of GaN only in the openings, resulting in the formation of regular arrays of nanowires 704 without any significant growth on the surface of the Ti mask. In various embodiments, the optimal growth condition included a Ga beam equivalent pressure (BEP) of approximately 3.7×10⁻⁷ Torr, a nitrogen flow rate of 0.86 sccm, and a growth temperature of 665° C. measured by pyrometer. After the formation of the n-GaN nanowire template 708, an active region consisting of six stacks of InGaN quantum disks 710 and AlGaN barriers 712 were grown, shown in the inset of FIG. 7A. The use of AlGaN barrier layer 712, instead of GaN, promotes the formation of core-shell-like nanoscale heterostructures, which effectively reduce nonradiative surface recombination and lead to high efficiency emission. In various embodiments, the growth of the active region 714 used a Ga BEP of 2.8×10⁻⁸ Torr, an Al BEP of 5.1×10⁻⁹ Torr, and an In BEP of 9.7×10⁻⁸ Torr at a growth temperature of 485° C. measured by pyrometer. To minimize electron overflow and facilitate hole injection, a 60 nm p-AlGaN cladding layer 716 and a heavily doped p⁺⁺-GaN/n⁺⁺-GaN tunnel junction 718 was grown, followed by a 60 nm n-GaN layer 720 with an n⁺⁺-GaN contact layer 722. In various embodiments, the growth conditions for these layers were nearly identical to those for n-GaN nanowire template 708 except for doping and an Al BEP of 5.1×10⁻⁹ Torr during the p-AlGaN layer 716. Shown in FIGS. 7B and 7C, the nanowires 704 exhibit highly uniform diameter and well-controlled morphology, which is characteristic of the SAE technique. FIG. 7B is a scanning electron microscopy (SEM) image of the as grown sample 704 in accordance with various embodiments of the present disclosure. FIG. 7C is a large area SEM image of the as grown sample 704 in accordance with various embodiments of the present disclosure. In various embodiments, the periodicity is 280 nm and the nanowire 704 diameter is approximately 255 nm. Detailed structural characterization was performed using scanning transmission electron microscopy (STEM). A cross-section of the nanowire 704 sample was prepared by focused ion beam. A high angle annular dark field (HAADF) image of one nanowire 704 is shown in FIG. 8A. FIG. 8A is a STEM-HAADF image of a single core-shell nanowire 704 with InGaN 710/AlGaN 712 multiple quantum disks in accordance with various embodiments of the present disclosure. Due to Ga-polarity, the nanowire 704 exhibits a pyramid-like morphology on the top. As such, InGaN quantum disk active region 714 is primarily formed on the semipolar planes of GaN. The dashed line 804 in FIG. 8A illustrates the interface between the n-GaN segment 708 and the InGaN quantum disk 710 active region. The entire InGaN/AlGaN quantum disk active region 714 is further delineated by the dashed lines 804 and 806 in FIG. 8A. In various embodiments, as the active region 714 is grown on the semipolar planes, the quantum disks 710 exhibit a unique evolving morphology as the growth proceeds. In various embodiments, detailed STEM characterizations revealed that they exhibited “Russian-Doll” type structure. Previous studies on similar structures grown by MBE revealed the presence of extensive atomic ordering instead of disorders commonly seen in conventional InGaN quantum wells. Energy-dispersive X-ray spectroscopy were performed to analyze the spatial distribution of In, Ga, and Al elements in the device active region 714. FIG. 8B shows the Distribution of In (top), Ga (center), and Al (bottom) around the active region 714 measured by energy-dispersive X-ray spectroscopy in accordance with various embodiments of the present disclosure. Specifically, the top two panels of FIG. 8B depict the distribution of In and Ga, respectively, confirming that the InGaN quantum disks 710 are formed at the center region of the nanowire 704. Very interestingly, the distribution of Al exhibits a distinct spontaneously formed Al-rich shell as indicated by the dashed boxes 810 in the bottom panel of FIG. 8B. The resulting InGaN core/AlGaN shell structure can drastically reduce nonradiative surface recombination by confining charge carriers in the center active region of the nanowire 704, which is very desirable to achieve high efficiency emission. Details of the Al-rich shell in the dashed box 802 in FIG. 8A were further examined and the result is shown in FIG. 8C. FIG. 8C is a High magnification HAADF image of the region corresponding to the dashed box 802 in FIG. 8A in accordance with various embodiments of the present disclosure. In various embodiments, each layer of AlGaN 712, manifested as the darker color regions due to the lower atomic number, is clearly resolved without any noticeable defects. In various embodiments, a line scan following the solid line 812 in FIG. 8C also measured six stronger signal peaks of Al as shown in FIG. 8D, further confirming the presence of Al-rich shell structure (e.g., 810). FIG. 8D is a graph of the profile of Al distribution along the solid line 812 in FIG. 8C in accordance with various embodiments of the present disclosure. In various embodiments, the formation of such Al-rich shell (e.g., 810) is because of the shorter migration length of Al adatoms compared to that of Ga and In adatoms. The Al adatoms impinging on the nanowire 704 sidewalls migrate slowly and cannot reach the top core region of the nanowire 704, thereby tending to stay near the sidewall and accumulating there. Such quantum disks formed on the semipolar plane with large bandgap AlGaN shell is highly beneficial for minimizing surface nonradiative recombination and enhancing light emission efficiency.

With reference to FIG. 7A, the nanowire arrays 704 were subsequently fabricated into micro-LED devices (e.g., 700). In various embodiments, the nanowire arrays 704 were firstly passivated by 50 nm Al₂O₃730 using atomic layer deposition (ALD) at 250° C., which also functioned as an insulation layer between the nanowires 704. Note that the layer of Al₂O₃730 can be referred to as a conformal passivation layer 730. Trimethylaluminum was used as the precursor. Then Al₂O₃730 was etched back by fluorine-based reactive ion etching to expose the top surface of nanowires 704. An additional 300 nm SiO₂ passivation and isolation layer 732 was deposited by plasma-enhanced chemical vapor deposition, which is followed by opening the current injection windows with standard photolithography and dry etching of SiO₂ 732. Subsequently, metal contacts consisting of 5 nm Ti, 5 nm Au and 180 nm indium tin oxide (ITO) 734 were deposited on top of the current injection windows and annealed at 550° C. for 1 min in 5% H₂ and 95% N₂ ambient. Similarly, n-type metal contact 736 was formed on the surface of the n-GaN template. Finally, a metal stack of 50 nm Ag, 150 nm Al and 50 nm Au was deposited on top of the nanowire arrays 704 to serve as a top reflecting layer. The schematic of the device before depositing the top reflecting layer is shown in FIG. 7A. It is noted that the conformal passivation layer 730 in various embodiments could be implemented with an oxide or any other insulating material that can be deposited using atomic layer deposition. For example, in various embodiments, the conformal passivation layer 730 could be implemented with any insulating material that is, but is not limited to, a good insulator and takes a low pinhole density coating, very conformal, very thin insulator, that can be deposited by atomic layer deposition.

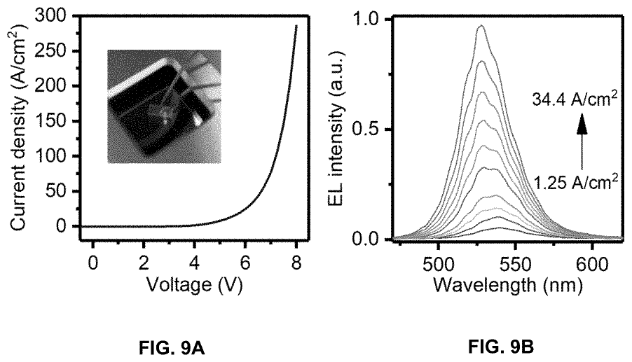

FIG. 9A is a graph of current-voltage characteristics of an InGaN nanowire micro-LED (e.g., 700) with a size of approximately 3 μm×3 μm and the inset is a photo of the device taken under room light in accordance with various embodiments of the present disclosure. A turn on voltage of approximately 4.5 V is measured and a relatively high current density of 285 A/cm² can be reached at 8 V. The relatively high turn-on voltage is likely due to the over etching of p-GaN contact layer during the etching of Al₂O₃730 and nonoptimized doping of the n-GaN layer 708. The inset is the photo of a micro-LED device (e.g., 700) with a dimension of approximately 3 μm×3 μm under room light, which is easily visible despite the small dimensions. FIG. 9B is a graph of electroluminescence (EL) spectra measured under different injection current densities at room temperature in accordance with various embodiments of the present disclosure. Electroluminescence (EL) spectra measured under various injection currents are displayed in FIG. 9B. A single pronounced emission around 535 nm is measured. As the current density increases from 1.25 A/cm² to 34.4 A/cm², the peak wavelengths exhibit a blue shift from 539.7 nm to 527.7 nm. This wavelength shift is similar or smaller than other reports on high efficiency quantum well LEDs with similar emission wavelengths, which is attributed to the reduced polarization field in the quantum disks formed on the semipolar planes. The full-width-at-half-maximum of the spectra slightly broadens from 33.8 nm to 34.7 nm, which is negligible compared to commonly observed broadening in quantum well structures. In various embodiments, note that the nanowire structure can be readily designed and engineered to form a photonic crystal that can tailor the emission properties for ultra-stable emission wavelength and narrow emission linewidth.

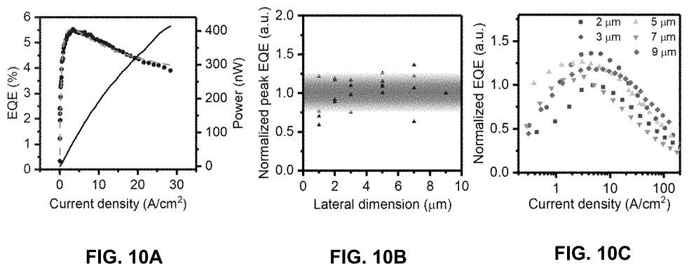

In various embodiments, the EQE was further examined in detail. The output power was measured utilizing a calibrated silicon detector. The output power increased near-linearly with the current density, shown in FIG. 10A. FIG. 10A is a graph in accordance with various embodiments of the present disclosure. More specifically, FIG. 10A shows variations of the measured (dot curve), fitted (dashed curve) EQE (left axis), and measured output power (solid curve) of the approximately 3 μm×3 μm micro-LED with current density in accordance with various embodiments of the present disclosure. A sharp increase in EQE was seen, and the EQE reached a peak value of approximately 5.5% at a current density of 3.4 A/cm². Such behavior is similar to that of conventional high efficiency large area LEDs. A drop of EQE to 3.9% is observed at an injection current of 28 A/cm². The correlation of EQE with the size of micro-LEDs was examined in various embodiments. Several groups of devices with different lateral dimensions, where the diameter and spacing of nanowires are consistent in each group, are identified. The device peak EQE in each group is normalized by that of the device with a size of approximately 9 μm×9 μm. FIG. 10B is a graph of a summary of normalized peak EQE of devices with different dimensions in accordance with various embodiments of the present disclosure. As shown in FIG. 10B, the normalized peak EQE of most devices is distributed between 0.75 and 1.25 and the correlation with the device lateral dimension is still unclear. It is also noticed that a relatively small dependence of EQE on size for green quantum well micro-LEDs was recently reported. FIG. 10C is a graph of normalized EQE of some representative devices with different lateral dimensions in accordance with various embodiments of the present disclosure. The variations of EQE with current density for some representative devices are further shown in FIG. 10C, which all exhibit similar trends and peak efficiency values, despite large variations of the device sizes. Shown in FIG. 10C, the peak EQE values occur at current densities of approximately 5 A/cm², 5 A/cm², 3 A/cm², 3 A/cm², and 4 A/cm² for devices with lateral dimensions of 2 μm, 3 μm, 5 μm, 7 μm, and 9 μm, respectively. There is a very small shift in the current densities, e.g., from approximately 3-4 A/cm² to approximately 5 A/cm² with decreasing the device lateral dimension from 9 μm to 2 μm. For nanowire micro-LEDs, because the fundamental building blocks for each micro-LED, regardless of the device dimensions, consist of highly uniform nanowire structures with greatly minimized surface recombination, the dependence on device sizes is expected to be small, if device fabrication process is optimized. Unlike conventional quantum well micro-LEDs, the fabrication of nanowire micro-LEDs in various embodiments does not involve dry-etching of the active region, thereby eliminating surface-induced damage, defects, states, and undesired impurity incorporation. The variation of the actual EQE is attributed to the nonoptimal fabrication process and some variations amongst the nanostructures. However, it is worth mentioning that the ultimate EQE is likely dependent on the size and design of the individual nanowires 704.

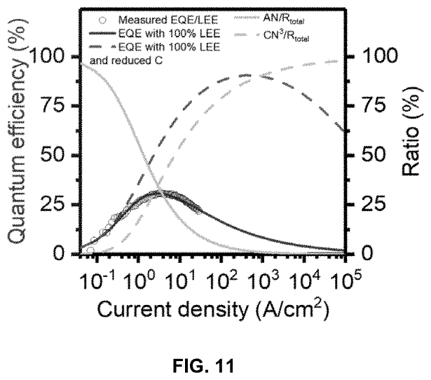

In various embodiments, detailed analysis was performed for the EQE of InGaN nanowire micro-LEDs (e.g., 700). The conventional ABC model was used to fit the measured EQE to derive the actual values of A, B, and C. The contributions from the terms AN, BN², and CN³ to the total recombination rate Rₜₒₜₐₗ were also examined to reveal the dominant mechanism of recombination. The fitted curve (dashed curve) is shown in FIG. 10A, which is in good agreement with the experimental data. The contribution of each term is further shown in FIG. 11 (right axis). FIG. 11 is a graph in accordance with various embodiments of the present disclosure. A peak internal quantum efficiency (IQE) of approximately 31%, which is the maximum attainable EQE assuming ideal light extraction, is derived for the presented device. Comparing with the experimentally measured peak EQE of 5.5%, the light extraction efficiency (LEE) is estimated to be 17.8%, which can be readily improved by proper device packaging. In order to obtain the actual values of A, B and C, an assumption of B value is made because the fitting gives the relative relations between A, C and B. The value of B is assumed to be 1×10⁻¹¹ cm³ s⁻¹ based on previous studies. Consequently, the coefficients A and C are derived to be A=5.47×10⁶ s⁻¹ and C=2.32×10⁻²⁹ cm⁶ s⁻¹. Given the intrinsically dislocation-free nature of InGaN nanowires, it is reasonable to conclude that further optimization of the active region growth will lead to a smaller A, thereby significantly enhancing the IQE. For example, by utilizing high temperature MBE as recently demonstrated for AlN, the presence of point defects can be drastically reduced. The obtained C value, on the other hand, is significantly higher than previously reported values for Auger coefficient, suggesting the presence of electron overflow and/or carrier leakage. Further optimization of the electron blocking layer and epitaxy conditions is expected to minimize the adverse effect of electron overflow. Based on these considerations, it is predicted that the presented InGaN nanowire micro-LEDs can exhibit a maximum EQE up to 90%, shown as the darker dashed curve in FIG. 11, by minimizing electron overflow, reducing the formation of point defects in the active region, and optimizing the LEE.

With reference to FIG. 11, Left axis: EQE of InGaN nanowire micro-LEDs (solid darker curve) with proper device packaging (assuming 100% LEE) based on the ABC model analysis. The estimated IQE (circles) based on the measured EQE divided by the light extraction efficiency is also shown for comparison. Right axis: estimated contribution of AN (solid light grey curve) and CN³ (dashed light grey curve) to the total recombination rate. The IQE, or maximum achievable EQE (darker dashed curve) is also estimated for an InGaN nanowire LED with an Auger coefficient C=5×10⁻³² cm⁶ s⁻¹, while keeping A and B coefficients as derived.

In conclusion, InGaN nanowire micro-LEDs (e.g., 700) with relatively high efficiency in the green wavelength are demonstrated in various embodiments. Owing to the reduced polarization field in the active region 714 on the semipolar plane, the emission wavelength shift and linewidth broadening are relatively small compared to conventional quantum well LEDs. In various embodiments, the presence of Al-rich shell (e.g., 810) contributes to the reduction of surface nonradiative recombination. In various embodiments, a relatively high EQE of approximately 5.5% is achieved for a 3 μm×3 μm green micro-LED at a current density of 3.4 A/cm². In various embodiments, the EQE of such nanowire-based micro-LEDs exhibits variations mostly within a range of 25% of the average value. In various embodiments, a peak IQE or maximum attainable EQE of 31% is estimated from an analysis based on the ABC model, indicating LEE as the major bottleneck for achieving higher EQE. In various embodiments, further reduction of nonradiative recombination and electron overflow are also expected to significantly boost the EQE. Various embodiments of the present disclosure reveal routes towards high efficiency operation of nanowire based micro-LEDs.

Note that the following are examples in accordance with various embodiments of the present disclosure.

Example 1. A light emitting diode (LED) including:
a plurality of nanowires, wherein each of the plurality of nanowires includes a tunnel junction;
a conformal passivation layer formed by atomic layer deposition (ALD) between the plurality of nanowires;
wherein the LED is operable for emitting light;
wherein the LED has an external quantum efficiency (EQE) greater than 5%; and
wherein the LED is in the range of 1-10 micrometers in lateral dimension.

Example 2. The LED of Example 1, wherein the conformal passivation layer includes Al₂O₃.

Example 3. The LED of Example 1, wherein the conformal passivation layer includes an oxide.

Although various subject matter of the present disclosure has been described in language specific to structural features and/or methodological acts, it is to be understood that the various subject matter defined in the present disclosure is not necessarily limited to the specific features or acts described herein. Rather, the specific features and acts described herein are disclosed as various example forms of implementing the present disclosure.

Various embodiments of the present disclosure are thus described. While the present disclosure has been described in particular embodiments, it should be appreciated that the present disclosure should not be construed as limited by such embodiments, but rather construed according to the following claims.

What is claimed is:

1. A nitrogen-polar (N-polar) nanowire comprising:
an indium gallium nitride (InGaN) quantum well formed by selective area growth;
wherein the N-polar nanowire is operable for emitting light.

2. The N-polar nanowire of claim 1, wherein the N-polar nanowire is a light emitting diode (LED).

3. The N-polar nanowire of claim 2, wherein the N-polar nanowire LED has an external quantum efficiency (EQE) greater than 10%.

4. The N-polar nanowire of claim 3, wherein the N-polar nanowire LED comprises a lateral dimension less than 1 micrometer.

5. The N-polar nanowire of claim 2, wherein the N-polar nanowire LED comprises a lateral dimension less than 1 micrometer.

6. The N-polar nanowire of claim 1, wherein the N-polar nanowire comprises a lateral dimension less than 1 micrometer.

7. The N-polar nanowire of claim 3, wherein the light comprises green light.

8. The N-polar nanowire of claim 1, wherein the N-polar nanowire comprises a plurality of InGaN quantum disks and a plurality of aluminum gallium nitride (AlGaN) barrier layers.

9. The N-polar nanowire of claim 1, further comprising a p-doped AlGaN layer.

10. The N-polar nanowire of claim 1, further comprising an InGaN layer.

11. A light emitting diode (LED) comprising:
an N-polar nanowire formed by selective area growth; and
wherein the LED comprises a lateral dimension less than 1 micrometer.

12. The LED of claim 11, wherein the N-polar nanowire further comprises an InGaN layer.

13. The LED of claim 11, wherein the LED is operable for emitting green light.

14. The LED of claim 13, wherein the LED has an external quantum efficiency (EQE) greater than 10%.

15. The LED of claim 11, wherein the N-polar nanowire further comprises a plurality of quantum disks.

16. The LED of claim 11, wherein the N-polar nanowire further comprises an AlGaN quantum barrier layer.

17. The LED of claim 11, wherein the selective area growth comprises selective area epitaxy.

18. A light emitting diode (LED) comprising:
a plurality of nanowires, wherein each of the plurality of nanowires comprises a tunnel junction;
a conformal passivation layer formed by atomic layer deposition (ALD) between the plurality of nanowires;
wherein the LED is operable for emitting light;
wherein the LED has an external quantum efficiency (EQE) greater than 5%; and
wherein the LED is in the range of 1-10 micrometers in lateral dimension.

19. The LED of claim 18, wherein the conformal passivation layer comprises Al₂O₃.

20. The LED of claim 18, wherein the conformal passivation layer comprises an oxide.
